(19) United States
(12) Patent Application Publication
(10) Pub. No.: US 2025/0051511 A1
(43) Pub. Date: Feb. 13, 2025

(54) INDANEDIONE-BASED CONJUGATED POLYMER FOR POLYMER SOLAR CELL DONOR, AND POLYMER SOLAR CELL COMPRISING SAME

(71) Applicant: PUKYONG NATIONAL UNIVERSITY INDUSTRY-UNIVERSITY COOPERATION FOUNDATION, Busan (KR)

(72) Inventor: Joo Hyun KIM, Busan (KR)

(73) Assignee: PUKYONG NATIONAL UNIVERSITY INDUSTRY-UNIVERSITY COOPERATION FOUNDATION, Busan (KR)

(21) Appl. No.: 18/921,478

(22) Filed: Oct. 21, 2024

Related U.S. Application Data
(63) Continuation of application No. PCT/KR2022/016074, filed on Oct. 20, 2022.

(30) Foreign Application Priority Data
Apr. 21, 2022 (KR) 10-2022-0049613

(51) Int. Cl. C08G 61/12; H10K 30/30; H10K 30/50; H10K 30/81; H10K 85/10; H10K 85/60; H10K 101/30; H10K 101/50

(52) U.S. Cl. CPC C08G 61/126; H10K 30/30; H10K 30/50; H10K 85/113; H10K 85/151; H10K 85/657; C08G 2261/145; C08G 2261/146; C08G 2261/149; C08G 2261/15; C08G 2261/3223; C08G 2261/3243; H10K 30/81; H10K 2101/30; H10K 2101/50

(57) ABSTRACT

The present invention relates to a conjugated polymer compound for a polymer solar cell donor represented by the following chemical formula 1 and a polymer solar cell comprising same:

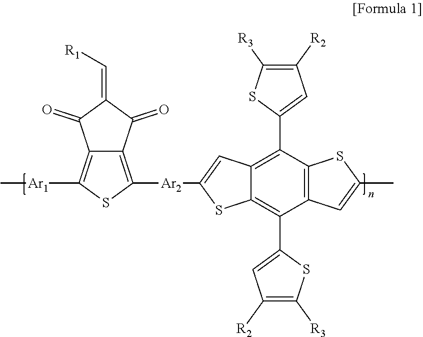

(in chemical formula 1 above, n is an integer greater than or equal to 2, Ar₁ and Ar₂ are each independently substituted or unsubstituted thienylene, substituted or unsubstituted thieno[3,2-b]thiophene, or a bond, R₁ is substituted or unsubstituted 2-thienyl or substituted or unsubstituted phenyl, R₂ is hydrogen or fluorine, and R₃ is 2-ethylhexyl).

### CROSS-REFERENCE TO RELATED APPLICATIONS

This application is a continuation of International Application No. PCT/KR2022/016074 filed on Oct. 20, 2022, which claims priority to Korean Patent Application No. 10-2022-0049613 filed on Apr. 21, 2022, the entire contents of which are herein incorporated by reference.

### TECHNICAL FIELD

The present disclosure relates to a conjugated polymer compound for a donor included in an active layer of a polymer solar cell, and a polymer solar cell comprising the same.

### BACKGROUND ART

Polymer solar cells (PSCs), which are based on a bulk heterojunction (BHJ) structure composed of a blend of conjugated electron donors and electron acceptors and are fabricated by solution-processing, have attracted great attention as electricity-generating devices due to their excellent properties such as light weight, mechanical flexibility, and low-cost manufacturing of large-area.

Conjugated polymer donors included in the active layer of the bulk heterojunction structure generally, have a D-A type that includes alternating electron donors (D) and electron acceptors (A) along a polymer backbone, thereby reducing a bandgap through the creation of intramolecular charge transfer (ICT) states.

For example, high-performance polymer donors of the D-A type composed of electron-donating groups such as benzodithiophene (BDT) and fluorinated benzodithiophene (BDTF), and electron-accepting groups such as benzotriazole (BTA), benzodithiophene-dione (BDD), and quinoxaline (Qx), have recently been proposed to improve the photovoltaic performance of the polymer solar cells.

### DISCLOSURE

### Technical Problem

An object of the present disclosure is to provide a novel conjugated polymer compound for an active layer donor for implementing a polymer solar cell with excellent photovoltaic performance, and a polymer solar cell comprising the same.

### Technical Solution

In one aspect, the present disclosure provides a conjugated polymer compound for a polymer solar cell donor represented by the following Formula 1:

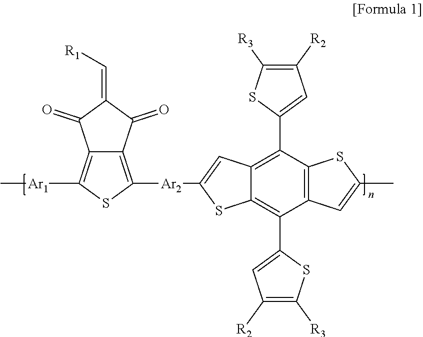

wherein
n is an integer greater than or equal to 2,
Ar₁ and Ar₂ are each independently substituted or unsubstituted thienylene, substituted or unsubstituted thieno[3,2-b]thiophene, or a bond,
R₁ is substituted or unsubstituted 2-thienyl or substituted or unsubstituted phenyl,
R₂ is hydrogen or fluorine, and
R₃ is 2-ethylhexyl.

In addition, the present disclosure provides a conjugated polymer compound for a polymer solar cell donor represented by the following Formula 2:

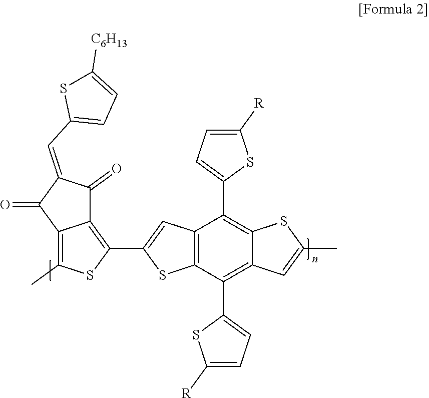

wherein R is 2-ethylhexyl.

Also, the present disclosure provides a conjugated polymer compound for a polymer solar cell donor represented by the following Formula 3:

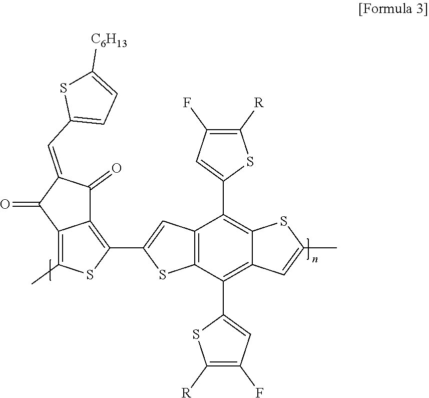

wherein R is 2-ethylhexyl.

Further, the present disclosure provides a conjugated polymer compound for a polymer solar cell donor represented by the following Formula 4:

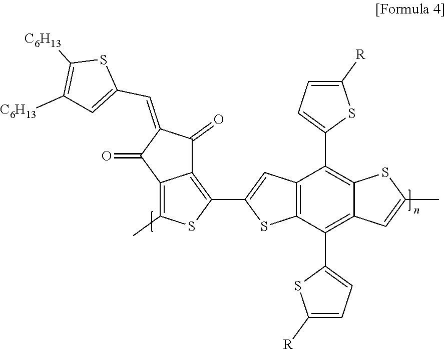

wherein R is 2-ethylhexyl.

Furthermore, the present disclosure provides a conjugated polymer compound for a polymer solar cell donor represented by the following Formula 5:

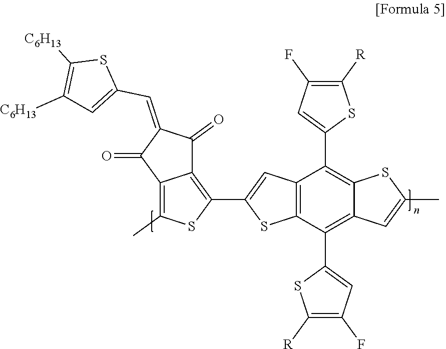

wherein R is 2-ethylhexyl.

Additionally, the present disclosure provides a conjugated polymer compound for a polymer solar cell donor represented by the following Formula 6:

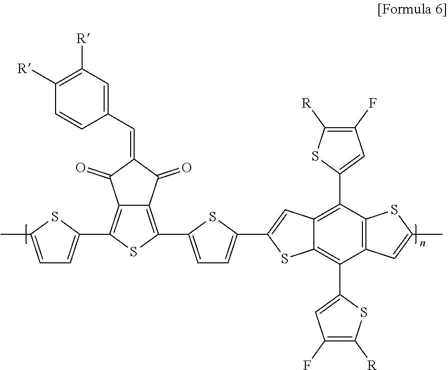

wherein
R is 2-ethylhexyl, and
R′ is 2-ethylhexyloxy.

Further, the present disclosure provides a conjugated polymer compound for a polymer solar cell donor represented by the following Formula 7:

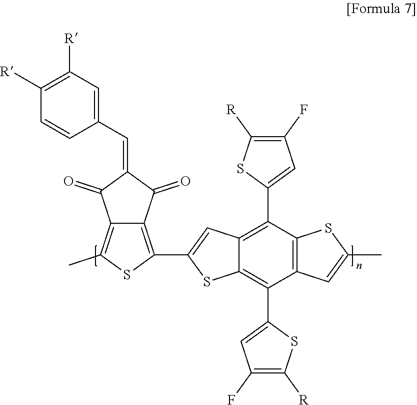

wherein
R is 2-ethylhexyl, and
R′ is 2-ethylhexyloxy.

In another aspect, the present disclosure provides a polymer solar cell having an active layer including the conjugated polymer compound as a donor.

Here, a stacked structure of the polymer solar cell according to the present disclosure and a material of each layer are not particularly limited.

For example, the polymer solar cell according to the present disclosure is an inverted-type polymer solar cell (iPSC) including: a cathode formed on a transparent substrate; an active layer having an electron donor composed of the conjugated polymer compound, and an electron acceptor; and an anode.

The substrate may be made of a transparent material with high light transmittance, and representative examples thereof include glass, polycarbonate, polymethyl methacrylate, polyethylene terephthalate, polyamide, polyethresulfone, and the like.

In addition, the active layer may be formed of a mixture containing an electron donor composed of the conjugated polymer compound, and an electron acceptor in a heterojunction structure. In this case, it is preferable to use a non-fullerene-based acceptor such as 2,2′-((2Z,2′Z)-((12,13-bis(2-butyloctyl)-12,13-dihydro-[1,2,5]thiadiazolo[3,4-e]thieno[2″,3″:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile (Y6BO) as the electron acceptor.

The anode and cathode may be formed of metal oxides such as indium tin oxide (ITO), SnO₂, IZO (In₂O₃—ZnO), aluminum doped ZnO (AZO), and gallium doped ZnO (GZO), aluminum (Al), transition metals such as silver (Ag), gold (Au), and platinum (Pt), rare earth metals, and semimetals such as selenium (Se), and are preferably formed in consideration of a work function.

A specific example of a polymer solar cell according to the present disclosure includes a polymer solar cell in which an ITO substrate; an active layer including an electron donor composed of a conjugated polymer compound represented by any one of Formulas 1 to 7 and an electron acceptor composed of Y6BO; a metal oxide layer including molybdenum oxide (MoO₃); and a silver (Ag) electrode layer, are sequentially stacked, wherein the polymer solar cell may further comprise a zinc oxide (ZnO) layer between the ITO substrate and the active layer.

### Advantageous Effects

The conjugated polymer for a polymer solar cell donor according to the present disclosure may have a D-A structure in which benzodithiophene (BDT) and fluorinated benzodithiophene (BDTF) as electron-donating units and indandione derivatives (TIND-HT or TIND-DHT) as electron-accepting units are directly combined, and may be usefully used as an active layer donor material for implementing a non-fullerene polymer solar cell with excellent photoelectric conversion efficiency.

### DESCRIPTION OF DRAWINGS

FIG. 1 is a diagram illustrating a process of synthesizing donor polymers (TIND-HT-BDT, TIND-HT-BDTF, TIND-DHT-BDT, and TIND-DHT-BDTF) in the examples herein.

FIG. 2 is a diagram illustrating a molecular structure of the donor polymers (TIND-HT-BDT, TIND-HT-BDTF, TIND-DHT-BDT, and TIND-DHT-BDTF) synthesized in the examples herein, and a chemical structure of Y6BO acceptor.

FIG. 3 is normalized UV-vis spectra of the donor polymer and Y6BO in a polymer film manufactured in the examples herein.

FIG. 4A is an energy level diagram of the donor polymer, Y6BO, and the other materials in the device fabricated in the examples herein, and FIG. 4B is a current density vs. voltage curves of the PSC under 1.0 sun illumination (inset: the dark conditions).

FIG. 5A is J_{Ph}/Jₛₐₜ-V_{eff} curves of the PSCs fabricated in the examples herein, and FIG. 5B is J_{Ph}-V_{eff} curves of the PSC.

FIG. 6A is curves illustrating a relationship between J_{SC} and light intensity of the PSC fabricated in the example herein, and FIG. 6B is curves illustrating a relationship between V_{OC} and light intensity.

FIGS. 7A to 7D are GIWAXS images of a film containing only the donor polymer prepared in examples herein, and FIG. 7E is a graph illustrating the corresponding line cut in in-plane (IP) and out-of-plane (OOP) directions.

FIGS. 8A to 8D are GIWAXS images of a donor polymer: Y6BO blend film manufactured in the examples herein, and FIG. 8E is a graph illustrating the corresponding line cut in in-plane (IP) and out-of-plane (OOP) directions.

### BEST MODE FOR INVENTION

In describing the present disclosure, if it is determined that a detailed description of a related known function or configuration may unnecessarily obscure the gist of the present disclosure, the detailed description will be omitted.

Since embodiments according to the concept of the present disclosure can make various changes and have various forms, specific embodiments will be illustrated in the drawings and described in detail in the present specification or in the application. However, it should be understood that this is not intended to limit embodiments according to the concept of the present disclosure to specific types of disclosure, and includes all changes, equivalents, and substitutes included in the spirit and technical scope of the present disclosure.

The terms used herein are only used to describe specific embodiments and are not intended to limit the present disclosure. Singular expressions include plural expressions unless the context clearly indicates otherwise. It should be understood that the term “comprise” or “have”, etc., as used herein is intended to specify the presence of implemented features, numbers, steps, operations, components, parts, or combinations thereof, and does not preclude in advance the existence or additional possibility of one or more other features or numbers, steps, operations, components, parts, or combinations thereof.

In addition, unless otherwise specified, the following terms and phrases used in the specification have the following meanings.

“Alkyl” is a hydrocarbon having normal, secondary, tertiary, or cyclic carbon atoms. For example, an alkyl group may have 1 to 20 carbon atoms (i.e., C₁-C₂₀ alkyl), 1 to 10 carbon atoms (i.e., C₁-C₁₀ alkyl), or 1 to 6 carbon atoms (i.e., C₁-C₆ alkyl). Examples of suitable alkyl groups include, but are not limited to, methyl (Me, —CH₃), ethyl (Et, —CH₂CH₃), 1-propyl (n-Pr, n-propyl, —CH₂CH₂CH₃), 2-propyl (i-Pr, i-propyl, —CH(CH₃)₂), 1-butyl (n-Bu, n-butyl, —CH₂CH₂CH₂CH₃), 2-methyl-1-propyl (i-Bu, i-butyl, —CH₂CH(CH₃)₂), 2-butyl (s-Bu, s-butyl, —CH(CH₃)CH₂CH₃), 2-methyl-2-propyl (t-Bu, t-butyl, —C(CH₃)₃), 1-pentyl (n-pentyl, —CH₂CH₂CH₂CH₂CH₃), 2-pentyl (—CH(CH₃)CH₂CH₂CH₃), 3-pentyl (—CH(CH₂CH₃)₂), 2-methyl-2-butyl (—C(CH₃)₂CH₂CH₃), 3-methyl-2-butyl (—CH(CH₃)CH(CH₃)₂), 3-methyl-1-butyl (—CH₂CH₂CH(CH₃)₂), 2-methyl-1-butyl (—CH₂CH(CH₃)CH₂CH₃), 1-hexyl (—CH₂CH₂CH₂CH₂CH₂CH₃), 2-hexyl (—CH(CH₃)CH₂CH₂CH₂CH₃), 3-hexyl (—CH(CH₂CH₃)(CH₂CH₂CH₃)), 2-methyl-2-pentyl (—C(CH₃)₂CH₂CH₂CH₃), 3-methyl-2-pentyl (—CH(CH₃)CH(CH₃)CH₂CH₃), 4-methyl-2-pentyl (—CH(CH₃)CH₂CH(CH₃)₂), 3-methyl-3-pentyl (—C(CH₃)(CH₂CH₃)₂), 2-methyl-3-pentyl (—CH(CH₂CH₃)CH(CH₃)₂), 2,3-dimethyl-2-butyl (—C(CH₃)₂CH(CH₃)₂), 3,3-dimethyl-2-butyl (—CH(CH₃)C(CH₃)₃, and octyl (—(CH₂)₇CH₃).

The term “substituted” with respect to alkyl, etc., for example, “substituted alkyl”, etc., refers to alkyl, etc., wherein one or more hydrogen atoms are each independently substituted with a non-hydrogen substituent. Typical substituents includes, but are not limited to, —X, —R, —O—, ═O, —OR, —SR, —S⁻, —NR₂, —N⁺R₃, =NR, —CX₃, —CN, —OCN, —SCN, —N═C═O, —NCS, —NO, —NO₂, =N₂, —N₃, —NHC(═O)R, —C(═O)R, —C(═O)NRR—S(═O)₂O—, —S(═O)₂OH, —S(═O)₂R, —OS(═O)₂OR, —S(═O)₂NR, —S(═O)R, —OP(═O)(OR)₂, —N(═O)(OR)₂, —N(═O)(O⁻)₂, —N(═O)(OH)₂, —N(O)(OR)(O⁻), —C(═O)R, —C(═O)X, —C(S)R, —C(O)OR, —C(O)O—, —C(O)SR, —C(S)SR, —C(O)NRR, —C(S)NRR, —C(═NR)NRR (wherein each X is independently halogen: F, Cl, Br, or I, and R is independently H, alkyl, aryl, arylalkyl, heterocycle, or a protecting group or prodrug moiety).

Hereinafter, the present disclosure will be described in detail with reference to examples.

### EXAMPLES

### 1. Synthesis of Monomers (TIND-HT and TIND-DHT)

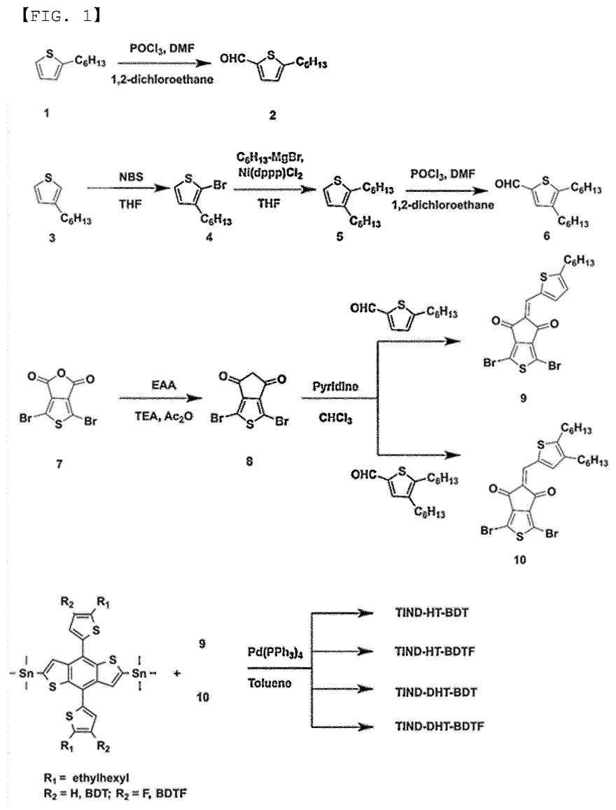

Monomers TIND-HT and TIND-DHT were synthesized by a Knoevenagel condensation reaction between 1,3-dibromo-4H-cyclopenta[c]thiophene-4,6(5H)-dione and 5-hexylthiophene-2-carbaldehyde or 4,5-dehexylthiophene-2-carbaldehyde (FIG. 1).

### (1) Synthesis of 5-hexylthiophene-2-carbaldehyde (Compound 2)

A mixture of 0.548 g (7.5 mmol) of DMF and 1.15 g (7.5 mmol) of POCl₃ was stirred at 0° C. for 30 minutes to prepare Vilsmeier's reagent; 1.30 mL of Vilsmeier's reagent was added to a solution of 0.785 g (4.6 mmol) of 2-hexylthiophene in 10 mL dichloroethane. The reaction was refluxed overnight at 90° C. under N₂ gas. After cooling to room temperature, an aqueous NaHCO₃ solution was added to the reaction mixture. The mixture was extracted with dichloromethane (MC), dried over MgSO₄, and the solvent was evaporated under reduced pressure. The red liquid was further purified by silica gel column chromatography using MC/hexane (6:4) to obtain the product as a light yellow liquid (0.92 g, 88.0%).

MS: [M⁺], m/z 196 ¹H NMR (400 MHz, CDCl₃, ppm): δ 9.78 (s, 1H), 7.59 (d, 1H), 6.88 (d, 1H), 2.84 (t, 2H), 1.67 (m, 2H), 1.29 (m, 6H), 0.86 (t, 3H). ¹³C NMR (400 MHz, CDCl₃, ppm): δ 182.75, 141.66, 137.13, 125.91, 31.53, 31.31, 30.91, 28.75, 22.59, 14.11.

### (2) Synthesis of 2-bromo-3-hexylthiophene (Compound 4)

3 g (17.8 mmol) of 3-hexylthiophene was dissolved in 40 mL of tetrahydrofuran (THF), and then 3.49 g (19.6 mmol) of N-bromosuccinimide (NBS) was slowly added thereto under ice bath conditions. The reaction was maintained at room temperature for 3 hours and monitored by TLC. The reaction was terminated by adding 100 mL of water, and then extracted with 100 mL of diethyl ether. The organic phase was collected and washed several times with brine. The resulting mixture was dried over MgSO₄, and then the solvent was evaporated under reduced pressure. Finally, the produce was purified by column chromatography using hexane as an eluent to obtain a clear oil (4.10 g, 93.4%).

MS: [M⁺], m/z 246. ¹H NMR (400 MHz, CDCl₃, ppm): δ 7.20 (d, 1H), 6.82 (d, 1H), 2.60 (t, 2H), 1.61 (m, 2H), 1.35 (m, 6H), 0.93 (t, 3H). ¹³C NMR (400 MHz, CDCl₃, ppm): δ 142.06, 128.34, 125.23, 108.93, 31.78, 29.86, 29.54, 29.05, 22.76, 14.25.

### (3) Synthesis of 4,5-dehexylthiophene-2-carbaldehyde (Compound 5)

In a two-necked flask, 5.41 g (21.9 mmol) of 2-bromo-3-hexylthiophene and 0.59 g (1 mmol) of Ni(dppp)Cl₂ were dissolved in 25 mL of THF. Hexyl-MgBr was slowly added to the reaction mixture under ice bath conditions. The mixture was then refluxed overnight under nitrogen conditions. The reaction was terminated by adding a saturated ammonium chloride solution, and the reaction mixture was further extracted with hexane. After washing several times with brine, the mixture was dried over MgSO₄ and the solvent was evaporated using a rotary evaporator. The product was purified by column chromatography using hexane as an eluent to obtain a yellow oil (4.90 g, 88.0%).

¹H NMR (400 MHz, CDCl3, ppm): δ 7.03 (d, 1H), 6.82 (d, 1H), 2.72 (t, 2H), 2.51 (t, 2H), 1.63 (m, 2H), 1.55 (m, 2H), 1.31 (m, 12H), 0.90 (t, 6H). ¹³C NMR (400 MHz, CDCl₃, ppm): δ 138.89, 137.78, 128.76, 120.96, 32.03, 31.84, 31.73, 30.94, 29.81, 29.30, 29.14, 28.31, 27.87, 22.73, 22.70, 14.19.

### (4) Synthesis of 4,5-dehexylthiophene-2-carbaldehyde (Compound 6)

A mixture of 6.95 g (95.1 mmol) of DMF and 14.58 g (95.1 mmol) of POCl₃ was stirred at 0° C. for 30 minutes to prepare Vilsmeier's reagent. The Vilsmeier's reagent was added slowly to a solution of 6.15 g (24.4 mmol) of 2,3-dihexylthiophene in 48 mL of dichloroethane. The reaction mixture was refluxed overnight under N₂ atmosphere. The reaction mixture was cooled to room temperature, and then an aqueous NaHCO₃ solution was added. The mixture was extracted with dichloromethane (MC), dried over MgSO₄, and the solvent was evaporated under reduced pressure. The brown oil was further purified by silica gel column chromatography using MC/hexane (6:4) to obtain the product as a yellow oil (6.60 g, 96.0%).

MS: [M⁺], m/z 280. ¹H NMR (400 MHz, CDCl₃, ppm): δ 9.78 (s, 1H), 7.03 (s, 1H), 2.77 (t, 2H), 2.52 (t, 2H), 1.66 (m, 2H), 1.57 (m, 2H), 1.31 (m, 12H), 0.89 (t, 6H). ¹³C NMR (400 MHz, CDCl₃, ppm): δ 182.69, 151.88, 140.11, 139.47, 138.48, 31.73, 31.60, 31.29, 30.52, 29.12, 29.01, 28.80, 28.13, 22.67, 22.62, 14.13.

### (5) Synthesis of 1,3-dibromo-4H-cyclopenta[c]thiophene-4,6(5H)-dione (Compound 8)

1 mL of triethylamine and 0.240 g (1.8 mmol) of ethylaceto acetate were added to a solution of 0.406 g (1.3 mmol) 4,6-dibromo-1H,3H-thieno[3,4-c]furan-1,2-dione in 1 mL of acetic anhydride under nitrogen. The reaction was then refluxed overnight at 65° C. The mixture was cooled to room temperature, then poured into diluted HCl under ice bath conditions and extracted with MC. The organic phase was evaporated and refluxed in concentrated HCl at 60° C. for 2 hours. The mixture was extracted with MC, dried over MgSO₄, and the solvent was evaporated under reduced pressure. The pink solid was purified by silica gel column chromatography using MC/hexane (10:1) as an eluent to obtain a pink solid (0.207 g, 51.0%).

MS: [M⁺], m/z 310. ¹H NMR (400 MHz, CDCl3, ppm): δ 3.51 (s, 2H). ¹³C NMR (400 MHz, CDCl₃, ppm): δ 187.07, 145.52, 113.05, 53.29.

### (6) Synthesis of 1,3-dibromo-5((5-hexylthiophen-2-yl)methylene)-4H-cyclopenta[c]thiophene-4,6(5H)-dione (Compound 9)

A mixture of Compound 2 (0.163 g, 0.827 mmol) and Compound 8 (0.309 g, 1 mmol) was dissolved in 6 mL of anhydrous chloroform with 3 drops of pyridine. The reaction mixture was refluxed overnight at 65° C. under nitrogen conditions. Water was poured into the reaction mixture, the resulting mixture was extracted with dichloromethane (MC), and then the organic layer was dried over MgSO₄. After removing the solvent under reduced pressure, the crude product was further purified by column chromatography using MC/hexane (2:1) as an eluent to obtain a yellow solid (0.403 g, 84.6%).

MS: [M⁺], m/z 488. ¹H NMR (400 MHz, CDCl3, ppm): δ 7.94 (s, 1H), 7.88 (d, 1H), 6.99 (d, 1H), 2.93 (t, 2H), 1.76 (m, 2H), 1.32 (m, 6H), 0.89 (t, 3H). ¹³C NMR (400 MHz, CDCl3, ppm): δ 181.17, 180.93, 164.38, 144.64, 143.65, 143.20, 139.98, 135.42, 129.46, 127.22, 112.12, 112.01, 31.54, 31.34, 28.92, 22.60, 14.13.

### (7) Synthesis of 1,3-dibromo-5((4,5-dihexylthiophen-2-yl)methylene)4Hcyclopenta[c]thiophene-4,6(5H)-dione (Compound 10)

A mixture of Compound 6 (0.306 g, 1.09 mmol) and Compound 8 (0.402 g, 1.30 mmol) was dissolved in 15 mL of anhydrous chloroform with 6 drops of pyridine. The reaction mixture was refluxed overnight at 65° C. under nitrogen conditions. Water was poured into the reaction mixture, the resulting mixtures was extracted with MC, and then the organic layer was dried over MgSO₄. After removing the solvent under reduced pressure, the crude product was further purified by column chromatography using MC/hexane (7:3) as an eluent to obtain a yellow solid (0.357 g, 57.0%).

MS: [M⁺], m/z 572. ¹H NMR (400 MHz, CDCl₃, ppm): δ 7.88 (s, 1H), 7.79 (s, 1H), 2.82 (t, 2H), 2.54 (t, 2H), 1.72 (m, 2H), 1.58 (m, 2H), 1.31 (m, 12H), 0.88 (t, 6H). ¹³C NMR (400 MHz, CDCl3, ppm): δ 181.38, 181.02, 159.76, 145.78, 143.68, 143.23, 141.84, 139.93, 133.65, 129.12, 111.80, 111.75, 31.72, 31.60, 31.32, 30.49, 29.42, 29.24, 29.18, 27.89, 22.68, 22.62, 14.17, 14.14.

### 2. Synthesis of Donor Polymers (TIND-HT-BDT, TIND-HT-BDTF, TIND-DHT-BDT, and TIND-DHT-BDTF)

The target polymers were synthesized by a Stille polycondensation reaction between the monomer BDT or BDTF and 1,3-dibromo-5((5-hexylthiophen-2-yl)methylene)-4H-cyclopenta[c]thiophene-4,6(5H)-dione (TIND-HT) to obtain TIND-HT-BDT and TIND-HT-BDTF polymers. The TIND-DHT-BDT and TIND-DHT-BDTF polymers were synthesized by the same manner using 1,3-dibromo-5((4,5-dihexylthiophen-2-yl)methylene)4H-cyclopenta[c]thiophene-4,6(5H)-dione (TIND-DHT) instead of TIND-HT (FIG. 1).

### (1) Synthesis of TIND-HT-BDT and TIND-HT-BDTF

In a Schlenk flask, the monomers TIND-HT (0.2 mmol), BDT or BDTF (0.2 mmol), and Pd(PPh₃)₄ (5%) were dissolved in 4 mL of dry toluene. The reaction mixture for TIND-HT-BDTF was stirred at 100° C. for 16 hours under N₂ atmosphere, while the reaction mixture for TIND-HT-BDT was stirred for 17 hours. Then, 2-tributylstanylthiophene and 2-bromothiophene were successively added as end-capping agents at 2-hour intervals. The reaction mixture was cooled to room temperature and poured into methanol. The precipitate was collected, dried, and further purified by Soxhlet extraction with methanol, hexane, acetone, and chloroform. Finally, the polymer was collected from chloroform fraction by precipitation from methanol and dried under vacuum.

TIND-HT-BDT (127 mg, 67.9%). ¹H NMR (400 MHz, CDCl₃, ppm): δ 2.95 (s), 1.58-0.99 (m). GPC=16909, PDI=2.38, TIND-HT-BDTF (140 mg, 72.1%). ¹H NMR (400 MHz, CDCl₃, ppm): δ 2.95 (s), 1.57-1.02 (m). GPC: Mn=10607, PDI=2.19.

### (2) Synthesis of TIND-DHT-BDT and TIND-DHT-BDTF

TIND-DHT-BDT and TIND-DHT-BDTF were synthesized in the same manner as TIND-HT-BDT described above using TIND-DHT and BDT or BDTF as monomers. Here, the reaction mixture for TIND-DHT-BDTF synthesis was stirred at 100° C. for 22 hours under N₂ atmosphere, and the reaction mixture for TIND-DHT-BDT synthesis was stirred for 30 hours.

TIND-DHT-BDT (160 mg, 80%). ¹H NMR (400 MHz, CDCl₃, ppm): δ 1.60-1.02 (m). GPC: Mn=35746, PDI=3.38, TIND-DHT-BDTF (108 mg, 54%). ¹H NMR (400 MHz, CDCl₃, ppm): δ 1.57-1.04 GPC: Mn=35009, PDI=2.45.

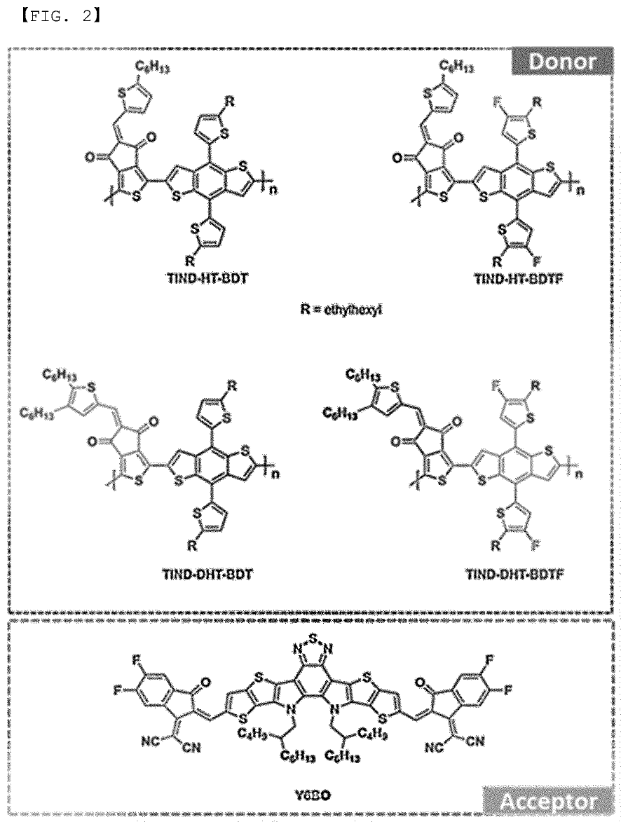

FIG. 2 illustrates the molecular structures of these four polymers. All polymers have excellent solubility in chloroform and chlorobenzene. The number average molecular weight (Mn) of the polymers was measured by gel permeation chromatography using THF as an eluent, and the corresponding values were 16.9, 10.6, 35.8, and 35.0 kDa for TIND-HT-BDT, TIND-HT-BDTF, TIND-DHT-BDT, and TIND-DHT-BDTF, respectively. The thermal stability of the polymers was evaluated by thermogravimetric analysis (TGA) under the N₂ atmosphere, and the polymers possess excellent thermal stability, with a decomposition temperature (Td, 5% weight loss) of 405° C., 392° C., 382° C., and 378° C. for TIND-HT-BDT, TIND-HT-BDTF, TIND-DHT-BDT and TIND-DHT-BDTF, respectively. According to differential scanning calorimetry (DSC) thermograms, any thermal transition such as glass transition and melting behavior were not observed.

### Experimental Example

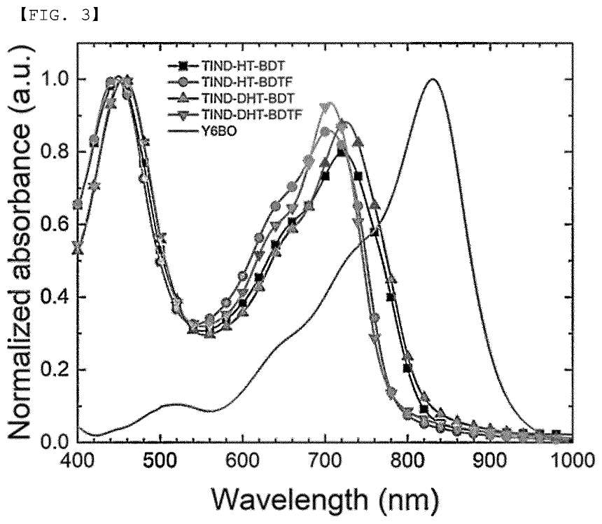

According to the absorption spectra of polymer films in FIG. 3, the polymer showed similar absorption features, with two absorption bands, one in the shorter wavelength region (400-550 nm) and another in the longer wavelength region (550-850 nm), which are generally detected in D-A polymers. The first peak corresponds to π-π* transition of a polymer backbone, while the second band is correlated with intramolecular charge transfer (ICT) between the BDT or BDTF donors and the TIND-HT and TIND-DHT acceptors. In a solid film, the absorption maximum is slightly red-shifted compared to the solution, which is attributed to the better aggregation of polymer chains in a solid state. Absorption edge of the TIND-DHT-BDT was red-shifted compared to the TIND-HT-BDT polymer. It suggests that the addition of the extra hexyl to a di-hexylthiophene (DHT) structure affects absorption properties of the polymer. Interestingly, the polymers with BDTF are blue-shifted compared to the corresponding BDT-based polymer. This result can be correlated to an increase in the bandgap of the polymer as a result of a deeper decrease in the HOMO energy level. The optical bandgaps of TIND-HT-BDT, TIND-HT-BDTF, TIND-DHT-BDT, and TIND-DHT-BDTF were deduced from the absorption edge and were 1.52 eV, 1.54 eV, 1.58 eV, and 1.60 eV, respectively, which followed the trend with the electrochemical bandgap. The absorption coefficients of TIND-HT-BDT, TIND-HT-BDTF, TIND-DHT-BDT, and TIND-DHT-BDTF were 4.08×10⁴ cm⁻¹, 7.31×10⁴ cm⁻¹, 7.41×10⁴ cm⁻¹, and 9.24×10⁴ cm⁻¹, respectively. The polymers with F-substituents (TIND-HT-BDTF and TIND-DHT-BDTF) have higher absorption coefficient values than those of the non-fluorinated polymers (TIND-HT-BDT and TIND-DHT-BDT). As can be seen in FIG. 3, the absorption ranges of the polymer are complementary to that of a Y6BO acceptor, which is advantageous for solar energy absorption from the ultraviolet-visible to the near-infrared regions. The optical properties of TIND-HT-BDT, TIND-HT-BDTF, TIND-DHT-BDT, and TIND-DHT-BDTF are summarized in Table 1.

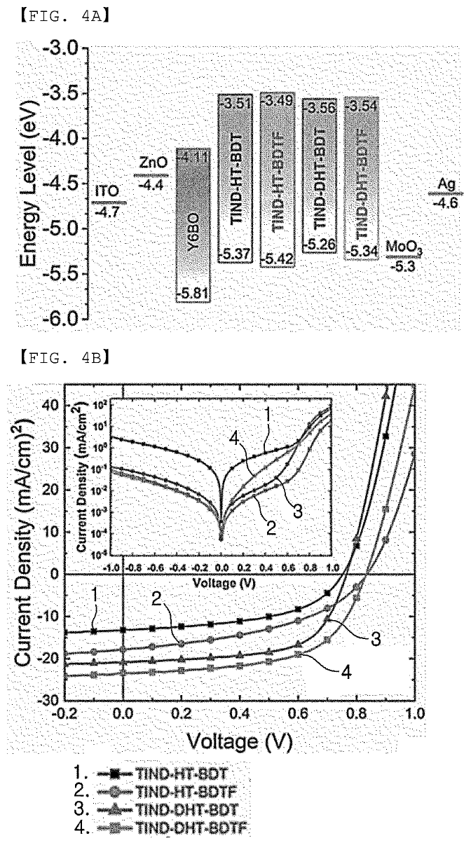

The HOMO/LUMO energy levels of the polymers were estimated from onset potentials of oxidation and reduction according to the cyclic voltammetry (CV). The HOMO and LUMO energy levels were −5.37 eV/−3.51 eV for TIND-HT-BDT, −5.42 eV/−3.49 eV for TIND-HT-BDTF, −5.26 eV/−3.56 eV for TIND-DHT-BDT, and −5.34 eV/−3.54 eV for TIND-DHT-BDTF, respectively. The HOMO levels were lowered in the TIND-HT-BDTF and TIND-DHT-BDTF polymers compared to the non-fluorinated polymers (TIND-HT-BDT and TIND-DHT-BDT). This trend can be explained by the introduction of fluorine atoms into a BDT unit, which has been also observed in donor polymers such as PM6 and PBDB-T-SF. The energy level diagram of the polymer, Y6BO, and the other materials in the device is illustrated in FIG. 4A. From the energy level data, the facile charge separation and transport processes are expected in inverted-type devices. To examine the exciton dissociation and charge transfer behavior in the active layer, photoluminescence (PL) measurements were performed in the neat polymers and the donor-acceptor blends. The PL emission of TIND-HT-BDT, TIND-HT-BDTF, TIND-DHT-BDT, and TIND-DHT-BDTF is in the range of 740-900 nm, whereas for the polymer blends with Y6BO, the PL peaks are effectively quenched for all the polymers. The PL quenching observed for these materials suggests that exciton dissociation and charge transfer between the polymer donor and the Y6BO are highly effective.

TABLE 1
Optical and electrochemical properties of polymers

| | | | Energy level (eV)^{b} | | |
|---|---|---|---|---|---|
| Polymer | (nm) | (eV)^{a} | HOMO | LUMO | (eV)^{b} |
| TIND-HT-BDT | 449,722 | 1.52 | −5.37 | −3.51 | 1.86 |
| TIND-HT-BDTF | 445,705 | 1.58 | −5.42 | −3.49 | 1.93 |
| TIND-DHT-BDT | 455,725 | 1.54 | −5.26 | −3.56 | 1.70 |
| TIND-DHT-BDTF | 455,705 | 1.60 | −5.34 | −3.54 | 1.80 |

^{a}Optical bandgap was obtained from the onset absorption edge of the film
^{b}Values obtained from the oxidation and reduction onset potentials of cyclic voltammogram

A density functional theory (DFT) at the B3LYP/6-31G** level of a Gaussian 09 program was used to evaluate the distribution of the frontier molecular orbitals of TIND-HT-BDT, TIND-HT-BDTF, TIND-DHT-BDT, and TIND-DHT-BDTF. For a simple calculation, all the alkyl chains in the TIND-HT or TIND-HT acceptors or BDT (or BDTF) donors were abbreviated to methyl groups. In addition, the polymer backbone was represented by two repeating units to facilitate the calculation. The DFT-calculated LUMO and HOMO energy levels of TIND-HT-BDT, TIND-HT-BDTF, TIND-DHT-BDT, and TIND-DHT-BDTF are −4.89 eV/−2.83 eV, −5.12 eV/−2.90 eV, −4.84 eV/−2.68 eV, and −5.01 eV/−2.79 eV, respectively. These results show that fluorine atoms in the BDT unit could simultaneously reduce both HOMO and LUMO energy levels of the polymer. The trend in the LUMO and HOMO energy levels calculated using theoretical analyses followed the trend in optical and electrochemical experiments.

Devices with inverted-type structure of ITO/ZnO/Donor:Y6BO/MoO₃/Ag were fabricated and tested to investigate the photovoltaic performances of TIND-HT-BDT, TIND-HT-BDTF, TIND-DHT-BDT, and TIND-DHT-BDTF as the electron donors. Here, Y6BO was used as an acceptor material. The photovoltaic performances were tested at diverse blend ratios between the donor and Y6BO acceptor and thickness of the active layer. An optimum blend ratio was 3:3 for TIND-HT-BDT, TIND-HT-BDTF, and TIND-DHT-BDT, and 3:4 for TIND-DHT-BDTF, respectively. As illustrated in FIG. 4A, efficient charge separation and charge transporting/collecting processes are expected in the devices. Current density-voltage (J-V) curves of the polymers at the optimized blend ratio under AM 1.5G simulated illumination are illustrated in FIG. 4B and the various parameters of the corresponding device are summarized in Table 2. The PCEs of the polymers successively increased in the order of TIND-HT-BDT (4.99%), TIND-HT-BDTF (6.21%), TIND-DHT-BDT (10.64%), and TIND-DHT-BDTF (11.1%). The V_{OC} values for the TIND-HT-BDT, TIND-HT-BDTF, TIND-DHT-BDT, and TIND-DHT-BDTF were 0.75, 0.84, 0.76, and 0.82 V, respectively. The polymers with BDTF units, TIND-HT-BDTF and TIND-DHT-BDTF showed higher V_{OC} values compared to the corresponding non-fluorinated polymers TIND-HT-BDT and TIND-DHT-BDT, respectively. It is attributed to the down-shifted HOMO level, which is induced by the fluorine atoms on the BDT unit. It was confirmed that the IPCE curves of the four devices covered broad wavelength range from 300 to 900 nm, showing that the donor polymers complemented well the solar light absorptions with the Y6BO acceptor.

The fill factor (FF) of the TIND-DHT-BDT polymer (FF=56.7%) is improved by the addition of hexyl chains, and the fill factor (FF) of TIND-DHT-BDTF (FF=59.9%) is further improved by the introduction of strong withdrawing fluorine (F). The calculated J_{sc} values from IPCE spectra are in accordance with the J_{sc} under 1.0 sun illumination. The trend of J_{sc} followed the trend of the absorption coefficients of the polymer except for TIND-DHT-BDTF. This is probably because the device based on TIND-DHT-BDTF has a different blend ratio from the device with the other three polymers.

Additionally, the series resistance (Rₛ) and shunt resistance (Rₛₕ) data were extracted from the J-V curves under dark condition (inset of FIG. 4B). The devices based on TIND-DHT-BDT (2.38 Ωcm²) and TIND-DHT-BDTF (3.40 Ωcm²) showed smaller Rₛ values compared to the devices based on TIND-HT-BDT (7.05 Ωcm²) and TIND-HT-BDTF (5.52 Ωcm²), which is consistent with the J_{sc} and FF trends of the corresponding devices. The Rₛₕ values for the devices increased in the order of TIND-HT-BDT (0.31 kΩcm²), TIND-HT-BDTF (0.32 kΩcm²), TIND-DHT-BDT (0.56 kΩcm²), and TIND-DHT-BDTF (0.57 kΩcm²), which also agrees well with the photovoltaic performance of the polymers.

In order to investigate the charge transporting properties of polymers, an electron-only device and a hole-only device with structures of ITO/ZnO (25 nm)/polymer:Y6BO/LiF/Al (100 nm) and ITO/PEDOT:PSS (35 nm)/polymer:Y6BO/Au (50 nm) were fabricated, respectively. The hole mobilities of the devices based on TIND-HT-BDT, TIND-HT-BDTF, TIND-DHT-BDT, and TIND-DHT-BDTF were 1.24×10⁻³ cm²V⁻¹s⁻¹, 2.01×10⁻³ cm²V⁻¹s⁻¹, 2.18×10⁻³ cm²V⁻¹s⁻¹, and 2.06×10⁻³ cm²V⁻¹s⁻¹, respectively, while their electron mobilities were 1.06×10⁻³ cm²V⁻¹s⁻¹, 1.58×10⁻³ cm²V⁻¹s⁻¹, 2.06×10⁻³ cm²V⁻¹s⁻¹, and 1.99×10⁻³ cm²V⁻¹s⁻¹, respectively. The hole/electron mobilities gradually increased in the order of TIND-HT-BDT, TIND-HT-BDTF, TIND-DHT-BDTF, and TIND-DHT-BDT, which agrees well with the J_{sc} trend of their corresponding photovoltaic devices. A hole/electron mobility ratio of the devices based on TIND-HT-BDT, TIND-HT-BDTF, TIND-DHT-BDT, and TIND-DHT-BDTF were 0.78, 0.71, 0.86, and 0.88, respectively, showing that the devices with TIND-DHT-BDT and TIND-DHT-BDTF were more balanced compared to the devices with TIND-HT-BDT and TIND-HT-BDTF. This result indicates better charge transport and extraction properties in the devices based on TIND-DHT-BDT and TIND-DHT-BDTF, which closely agrees with the higher FF values shown in the corresponding devices.

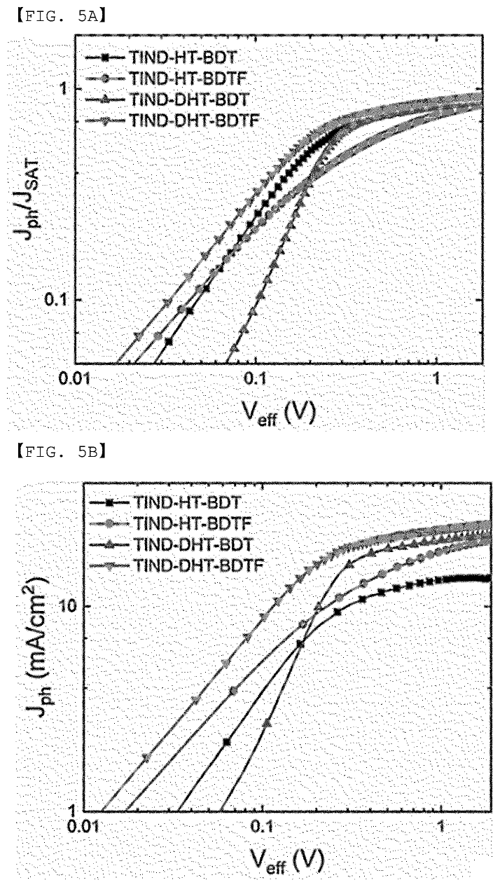

In addition, the relationship between photocurrent density (Jₚₕ) and effective voltage (V_{eff}) was calculated (J_{Ph}=J_{L} (current density under illumination)−J_{D} (current density under dark conditions) and V_{eff}=V₀ (voltage at J_{Ph}=0)−Vₐ (applied voltage)), to understand the charge transporting and collection properties of the devices. As illustrated in FIG. 5A, the V_{eff} values at saturated photocurrent regime (V_{Sat}) of devices based on TIND-HT-BDT, TIND-HT-BDTF, TIND-DHT-BDT, and TIND-DHT-BDTF were 0.29, 0.28, 0.27, and 0.23, respectively. This means that TIND-DHT-BDTF shows fast transition from a space-charge-limited regime to a saturation regime. The carrier transporting and collecting probability (J_{Ph}/J_{Sat}) can be determined from the saturation regime of J_{Ph}, where saturation current density J_{Sat} is calculated from a convergence value of J_{Ph}. Therefore, the J_{Ph}/J_{Sat} values at J_{sc} conditions of the PSC devices with TIND-HT-BDT, TIND-HT-BDTF, TIND-DHT-BDT, and TIND-DHT-BDTF under were 87.8, 76.8, 82.9, and 87.9%, respectively, which followed the same fill factor (FF) tendency of the corresponding devices. The maximum exciton generation rate (G_{MAX}) was estimated by using the equation G_{MAX} J_{Ph}/q·L, where q and L represent the electronic charge and the thickness of the active layer, respectively. The G_{MAX} at the J_{Sat} of the devices based on TIND-HT-BDT, TIND-HT-BDTF, TIND-DHT-BDT, and TIND-DHT-BDTF were 1.21×10²⁸, 1.34×10²⁸, 1.43×10²⁸, and 1.45×10²⁸, respectively. The G_{MAX} is correlated with the light absorption capability of the active layer, and in the Example, the trend of G_{MAX} of the devices followed the trend of the absorption coefficient of polymer films except for TIND-DHT-BDTF. This also presumably due to the device based on TIND-DHT-BDTF has a different blend ratio from the device with the other three polymers.

TABLE 2
Photovoltaic performance of the PSCs under
the illumination of AM 1.5 G, 100 mW/cm²

| | | | | | | R [symbol] | |
|---|---|---|---|---|---|---|---|
| | J [symbol] | V [symbol] | FF | PCE | R [symbol] | (kΩ | Calculated |
| Polymer | (mA/cm²) | (V) | () | () | (Ωcm²) | cm²) | (mA/cm²) |
| TIND-HT-BDT | 13.3 | 0.75 | 50.0 | 4.99 | 7.05 | 0.31 | 13.1 |
| | (12.8) | (0.75) | (50.1) | (4.84) | | | |
| TIND-HT-BDTF | 16.7 | 0.84 | 44.4 | 6.21 | 5.52 | 0.32 | 16.5 |
| | (16.6) | (0.84) | (44.5) | (6.19) | | | |
| TIND-DHT-BDT | 24.9 | 0.76 | 56.7 | 10.6 | 2.38 | 0.56 | 25.0 |
| | (24.8) | (0.75) | (56.2) | (10.5) | | | |
| TIND-DHT-BDTF | 22.6 | 0.82 | 59.9 | 11.1 | 3.40 | 0.57 | 22.4 |
| | (22.5) | (0.82) | (59.3) | (10.9) | | | |

[symbol]

indicates data missing or illegible when filed

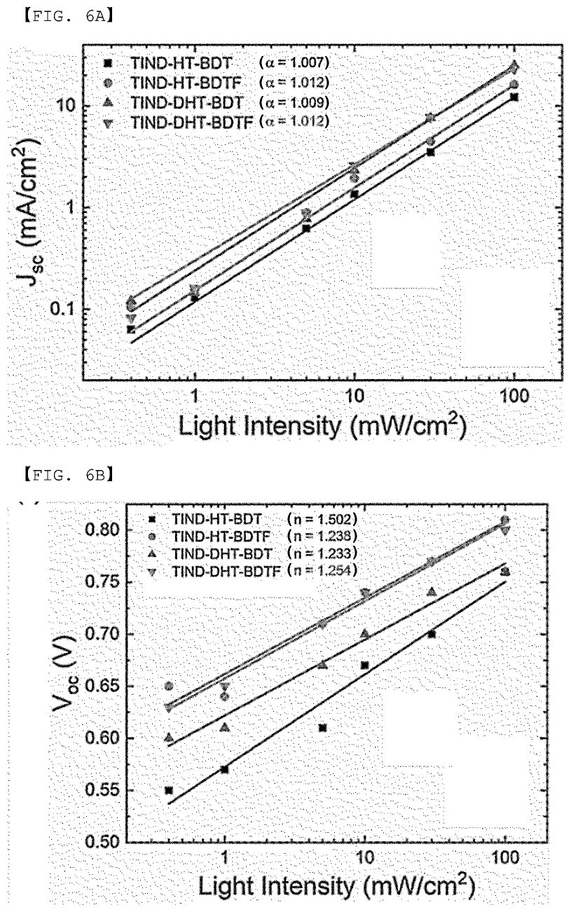

To examine bimolecular recombination in all PSCs, the dependence of J_{SC} values on light intensity of the four blend films was measured (FIG. 6A). The relationship between J_{SC} and light intensity is formulated as J_{SC}∝P_{light}_{^{α}}, where α is a slope of logarithmic coordinates. If all the free charges are carried out and collected without bimolecular recombination, the value of a should be equal to 1. The α values for TIND-HT-BDT, TIND-HT-BDTF, TIND-DHT-BDT, and TIND-DHT-BDTF were 1.007, 1.012, 1.009, and 1.012, respectively, which indicated that bimolecular recombination is minimized in the four devices. Additionally, trap-assisted recombination of each device was evaluated by plotting the V_{OC} values vs. the logarithmic dependence P_{light} (FIG. 6B). The V_{OC} linearly depends on ln P_{light} with a slope of nkT/q, where n is a scaling factor (1<n<2), k is a Boltzmann's constant, q is an elementary charge, and T is Kelvin temperature. If n is equal to 1 (slope=1 kT/q), the bimolecular recombination dominates in the device, and if n is equal to 2 (slope=2 kT/q), the monomolecular recombination (trap-assisted recombination) dominates in the device. In this Example, the n values for the optimized devices based on TIND-HT-BDT, TIND-HT-BDTF, TIND-DHT-BDT, and TIND-DHT-BDTF were 1.50, 1.24, 1.33, and 1.25, respectively. These results indicate that the trap-assisted recombination is inferior in the devices based on TIND-HT-BDTF, TIND-DHT-BDT, and TIND-DHT-BDTF. Therefore, these parameters correlated to a charge recombination process of the devices are consistent with the trend in their PCE values. The device parameters such as exciton generation, charge extraction, and charge recombination properties are improved by modifying the polymer structure. The results strongly support the trends in J_{SC}, FF, and PCE of the devices.

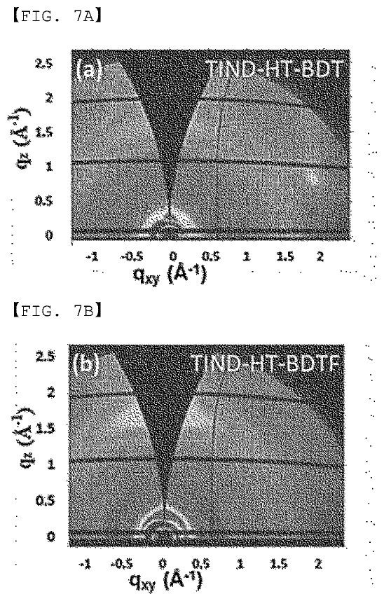

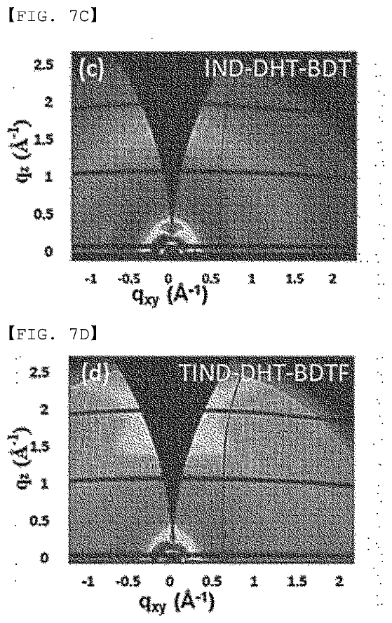

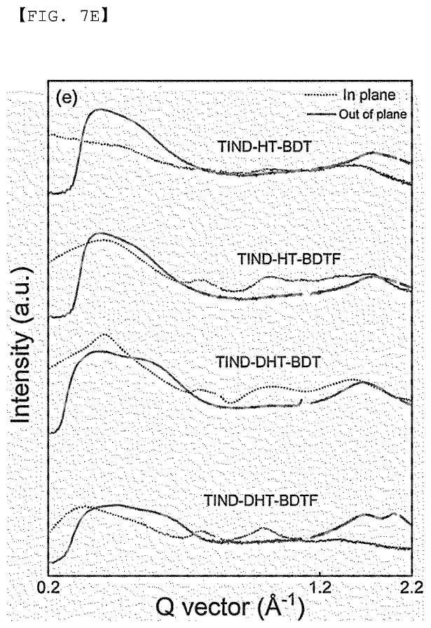

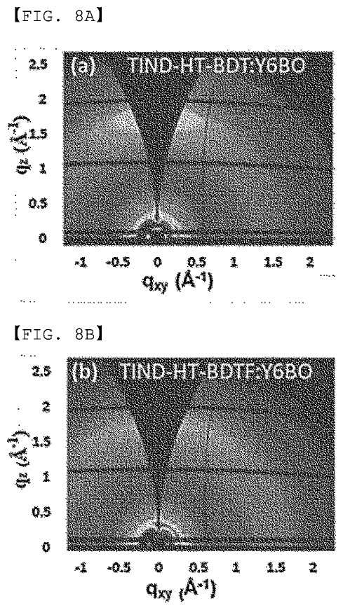

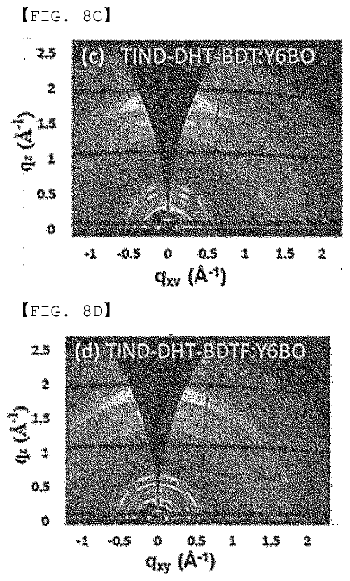

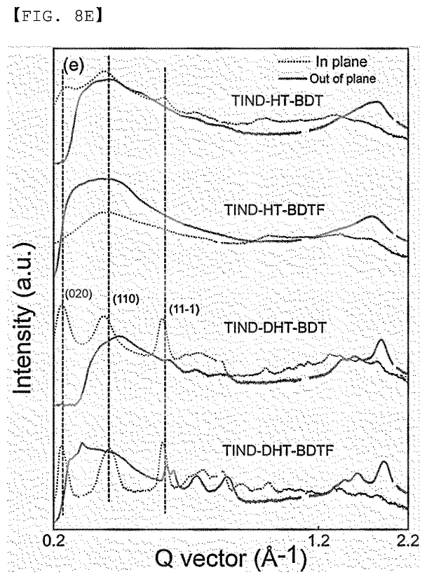

Since molecular ordering structures of the active layer have crucial roles in determining the photovoltaic performance of PSCs, grazing incidence wide-angle X-ray scattering (GIWAXS) measurements were performed to investigate the structural features of the active layer. The GIWAXS images of neat polymer films, blend films with Y6BO (FIGS. 7A to 7D and FIGS. 8A to 8D), and the corresponding line cut in in-plane (IP) and out-of-plane (OOP) directions of the neat polymer films and the blend films with Y6BO (FIGS. 7E and 8E) are illustrated in FIGS. 7 and 8, respectively. As illustrated in FIG. 7, TIND-HT-BDT, TIND-HT-BDTF, TIND-DHT-BDT, and TIND-DHT-BDTF films exhibited a broad (100) peaks at 1.69, 1.70, 1.59, and 1.61 Å⁻¹ along an OOP direction, respectively, which corresponded to π-π stacking distances of 3.72, 3.69, 3.95, and 3.90 Å, respectively. For TIND-DHT-BDT and TIND-DHT-BDTF, the π-π stacking distances were larger than those of the polymers with hexyl groups. Fluorine atoms on the BDT unit do not significantly affect the π-π stacking distance. A π-π stacking in the OOP direction corresponds to a face-on orientation relative to the surface, which is beneficial for the vertical charge transport between the electrodes of the photovoltaic cell. Another π-π stacking peak at 1.97 Å⁻¹ (3.19 Å) along the OOP direction was observed in TIND-DHT-BDTF film. The broad (100) peaks in TIND-HT-BDT, TIND-HT-BDTF, TIND-DHT-BDT, and TIND-DHT-BDTF at 0.286, 0.286, 0.284, and 0.252 Å⁻¹ along the IP direction, respectively, correspond to lamellar domains of 21.96, 22.04, 22.11, and 24.92 Å, respectively. The number of hexyl groups in the side chain of the polymer may affect the lamellar domain spacing distance of the polymer.

According to FIG. 8, for TIND-HT-BDT and TIND-HT-BDTF, the blend films with Y6BO have stronger π-π stacking in the OOP direction than in the IP direction, which means that the polymers in the blends have a face-on orientation relative to the surface. The (010) peaks in TIND-HT-BDT and TIND-HT-BDTF blend films were observed at 1.77 and 1.71 Å⁻¹, corresponding to π-π stacking distance of 3.64 and 3.66 Å, respectively. The peak intensity of (100) and (010) peaks along with the IP and OOP directions in the TIND-HT-BDT and TIND-HT-BDTF blend films with Y6BO become more intense relative to the corresponding neat polymer film, which comes from combined polymer and Y6BO diffraction. A diffraction pattern (100) of the TIND-HT-BDTF was overlapped with the diffraction patter (110) of Y6BO, but those patterns in the TIND-HT-BDT blend can be analyzed.

In TIND-DHT-BDT and TIND-DHT-BDTF blend films with Y6B, the peak intensity of the (010) peak along with the IP and OOP directions in the blend films become more intense relative to the corresponding neat polymer film, which also comes from combined polymer and Y6BO diffraction. The π-π stacking peaks of TIND-HT-BDT and TIND-HT-BDTF blend films appeared at 1.83 Å⁻¹ (3.43 Å) and 1.87 Å⁻¹ (3.36 Å), respectively. The TIND-DHT-BDT blend film showed three diffraction peaks in the low q_{xy} region (0.2 to 0.5 Å⁻¹) at 0.211, 0.279, and 0.417 Å⁻¹, respectively, which can be denoted as (020), (110), and (11-1) of Y6BO. The crystal unit cell was located to the surface due to the existence of (020) and (11-1) planes of Y6BO along the IP direction. Y6BO molecules will be relatively tilted to the surface because the strong (110) and (11-1) planes of Y6BO appeared along the IP direction. Similar features were also observed in the TIND-DHT-BDTF blend film. Therefore, molecular orientation could improve vertical charge transport in the device, which was directly reflected in the higher electron mobility observed in the devices based on TIND-DHT-BDT and TIND-DHT-BDTF. The GIWAXS measurement results well correlated with the device performances. Interestingly, two unknown peaks at 1.41 Å⁻¹ (4.44 Å) and 1.53 Å⁻¹ (4.11 Å) for the TIND-DHT-BDT blend film and two unknown peaks at 1.44 Å⁻¹ (4.37 Å) and 1.56 Å⁻¹ (4.03 Å) for the TIND-DHT-BDTF blend film were observed along the OOP direction. This may be another evidence that the PCEs of the devices based on TIND-DHT-BDT and TIND-DHT-BDTF are superior to those of the devices based on TIND-HT-BDTF and TIND-DHT-BDT.

In addition, transmission electron microscopy (TEM) measurements were performed to understand the morphology of the active layer. As a result, the active layer (polymer: Y6BO) of the four blend films showed uniform distribution, confirming that the polymer donors were well mixed with the Y6BO acceptor. However, the active layer based on TIND-DHT-BDTF showed the best nanoscale phase separation and better bicontinuous interpenetrating network among all the active layers investigated. The morphologies of the active layer of the films were consistent with the trend of FF values, among which the device based on TIND-DHT-BDTF had the highest FF value of 59.9%, leading to an enhancement in the PCE through efficient charge separation and charge transport.

It will be understood that the present disclosure is not limited to the above embodiments and can be manufactured in various different forms, and can be implemented in other specific forms without altering the technical idea or essential features of the present disclosure by those of ordinary skill in the art to which the present disclosure pertains. Therefore, it should be understood that the embodiments described above are illustrative in all respects and not limited.

### INDUSTRIAL APPLICABILITY

The conjugated polymer for a polymer solar cell donor according to the present disclosure may be usefully used as an active layer donor material for implementing a non-fullerene polymer solar cell with excellent photoelectric conversion efficiency.

1. A conjugated polymer compound for a polymer solar cell donor represented by the following Formula 1: 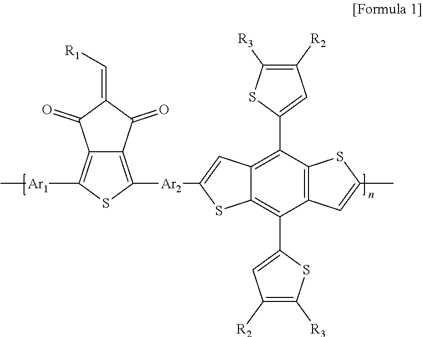
wherein
n is an integer greater than or equal to 2,
Ar₁ and Ar₂ are each independently substituted or unsubstituted thienylene, substituted or unsubstituted thieno[3,2-b]thiophene, or a bond,
R₁ is substituted or unsubstituted 2-thienyl or substituted or unsubstituted phenyl,
R₂ is hydrogen or fluorine, and
R₃ is 2-ethylhexyl.

2. The conjugated polymer compound for a polymer solar cell donor of claim 1, wherein the compound is represented by the following Formula 2: 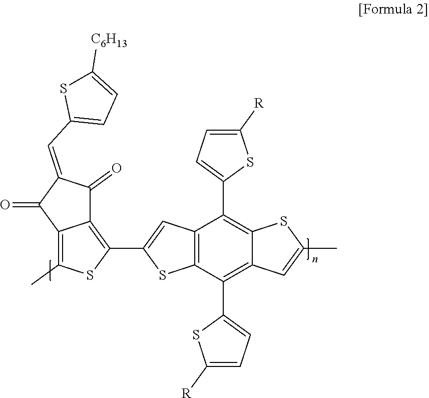
wherein R is 2-ethylhexyl.

3. The conjugated polymer compound for a polymer solar cell donor of claim 1, wherein the compound is represented by the following Formula 3: 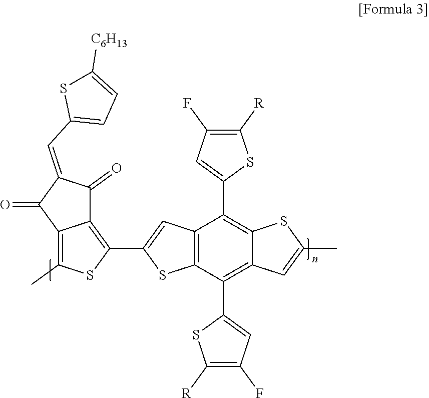
wherein R is 2-ethylhexyl.

4. The conjugated polymer compound for a polymer solar cell donor of claim 1, wherein the compound is represented by the following Formula 4: 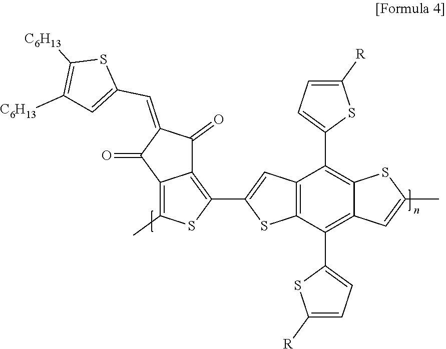
wherein R is 2-ethylhexyl.

5. The conjugated polymer compound for a polymer solar cell donor of claim 1, wherein the compound is represented by the following Formula 5: 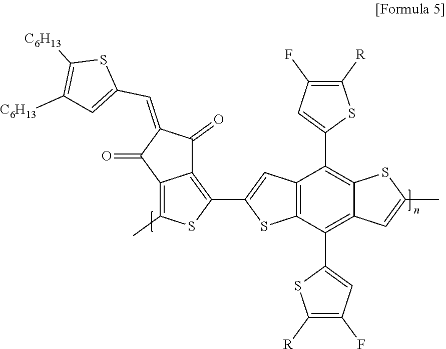
wherein R is 2-ethylhexyl.

6. The conjugated polymer compound for a polymer solar cell donor of claim 1, wherein the compound is represented by the following Formula 6: 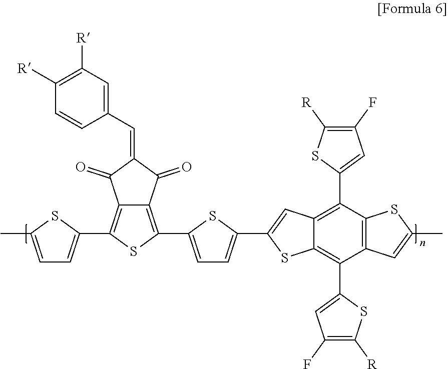
wherein
R is 2-ethylhexyl, and
R′ is 2-ethylhexyloxy.

7. The conjugated polymer compound for a polymer solar cell donor of claim 1, wherein the compound is represented by the following Formula 7: 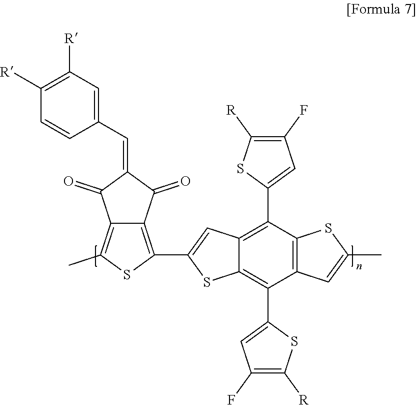
wherein
R is 2-ethylhexyl, and
R′ is 2-ethylhexyloxy.

8. A polymer solar cell having an active layer comprising the conjugated polymer compound of claim 1 as a donor.

9. The polymer solar cell of claim 8, wherein
the polymer solar cell is an inverted-type structure in which an ITO substrate;
an active layer comprising a donor composed of a conjugated polymer compound represented by any one of Formulas 1 to 7, and an acceptor;
a metal oxide layer comprising molybdenum oxide (MoO₃); and
a silver (Ag) electrode layer, are sequentially stacked.

10. The polymer solar cell of claim 9, wherein the acceptor is composed of 2,2′-((2Z,2′Z)-((12,13-bis(2-butyloctyl)-12,13-dihydro-[1,2,5]thiadiazolo[3,4-e]thieno[2″,3″:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile (Y6BO).

11. The polymer solar cell of claim 9, further comprising a zinc oxide (ZnO) layer between the ITO substrate and the active layer.
